(19) United States
(12) Patent Application Publication
(10) Pub. No.: US 2025/0366343 A1
(43) Pub. Date: Nov. 27, 2025

(54) DISPLAY DEVICE, MANUFACTURING METHOD THEREOF AND ELECTRONIC DEVICE INCLUDING DISPLAY DEVICE

(71) Applicant: SAMSUNG DISPLAY CO., LTD., YONGIN-SI, GYEONGGI-DO (KR)

(72) Inventors: Jee Hoon KIM, Yongin-si (KR); Woo Geun LEE, Yongin-si (KR); Dong Han KANG, Yongin-si (KR); Shin Hyuk YANG, Yongin-si (KR); Sung Gwon MOON, Yongin-si (KR)

(21) Appl. No.: 18/990,309

(22) Filed: Dec. 20, 2024

(30) Foreign Application Priority Data
May 21, 2024 (KR) 10-2024-0066067

(51) Int. Cl. H10K 59/80

(52) U.S. Cl. CPC H10K 59/80515

(57) ABSTRACT

A display device includes a substrate including light emitting areas and a non-light emitting area proximate to the light emitting areas. Anode electrodes are disposed on the substrate and respectively overlap the light emitting areas. A first insulating layer is disposed between the substrate and the anode electrodes and includes trenches overlapping the non-light emitting area. A second insulating layer is disposed between the first insulating layer and the anode electrodes. The second insulating layer includes first openings respectively overlapping some of the trenches, and fills the remaining trenches.

### CROSS-REFERENCE TO RELATED APPLICATION

This application claims priority to and the benefit of Korean Patent Application No. 10-2024-0066067, filed in the Korean Intellectual Property Office on May 21, 2024, the entire contents of which are herein incorporated by reference.

### TECHNICAL FIELD

The present disclosure relates to a display device. Specifically, the present disclosure relates to a display device, a manufacturing method thereof and an electronic device including the display device.

### DISCUSSION OF THE RELATED ART

As information technology develops, display devices, which serve to share information with users, are becoming increasingly important. While there are many different types of display devices used in electronic devices, popular examples include the liquid crystal display (LCD) device, an organic light emitting diode (OLED) display device, and the like.

### SUMMARY OF THE INVENTION

A display device includes a substrate including light emitting areas and a non-light emitting area proximate to the light emitting areas. Anode electrodes are disposed on the substrate and respectively overlap the light emitting areas. A first insulating layer is disposed between the substrate and the anode electrodes and includes trenches overlapping the non-light emitting area. A second insulating layer is disposed between the first insulating layer and the anode electrodes. The second insulating layer includes first openings respectively overlapping some of the trenches, and fills one or more of the remaining trenches.

The trenches may include first trenches that are defined between adjacent pairs of the anode electrodes. Second trenches may be are spaced apart from the anode electrodes and the first trenches in a plan view.

The second insulating layer may fill the second trenches, and the first openings may overlap the first trenches, respectively.

The display device may further include a passivation layer that is disposed between the first insulating layer and the second insulating layer and includes a material that is different from that of the first insulating layer.

The passivation layer may define second openings that respectively overlap the trenches.

Each of the second openings and each of the trenches may have an undercut shape.

The display device may further include a light emitting layer disposed on the anode electrodes.

The light emitting layer may be disconnected in areas overlapping the first trenches.

The display device may further include a cathode electrode disposed on the light emitting layer.

The cathode electrode may be disconnected in areas overlapping the first trenches.

A method of manufacturing a display device, includes forming a first insulating layer on a substrate that includes light emitting areas and a non-light emitting area proximate to the light emitting areas. Trenches are formed overlapping the non-light emitting area in the first insulating layer. A second insulating layer fills the trenches on the first insulating layer. First openings are formed in the second insulating layer by removing portions of the second insulating layer that overlap some of the trenches, respectively. Anode electrodes respectively overlap the light emitting areas on the second insulating layer.

The trenches may include first trenches and second trenches, and the forming of the trenches may include forming the first trenches between pairs of adjacent light emitting areas. The second trenches are formed spaced apart from the light emitting areas and the first trenches in a plan view.

The forming of the first openings may include removing portions of the second insulating layer respectively overlapping the first trenches.

The method may further include, after the forming of the first insulating layer and before the forming of the trenches in the first insulating layer, forming a passivation layer on the first insulating layer using a material that is different from that of the first insulating layer.

The method may further include, before the forming of the trenches, forming second openings overlapping the non-light emitting area in the passivation layer.

The trenches may be formed by removing portions of the first insulating layer overlapping the second openings through an ashing process.

Each of the second openings and each of the trenches may be formed to have an undercut shape.

The method may further include forming a light emitting layer on the anode electrodes so as to be disconnected in areas overlapping the first trenches.

The method may further include forming a cathode electrode on the light emitting layer so as to be disconnected in areas overlapping the first trenches.

The first insulating layer may be made of an organic material, and the passivation layer may be made of an inorganic material.

An electronic device includes a processor to provide input image data; and a display device to display an image based on the input image data, wherein the display device includes: a substrate including light emitting areas and a non-light emitting area proximate to the light emitting areas; anode electrodes disposed on the substrate and respectively overlapping the light emitting areas; a first insulating layer disposed between the substrate and the anode electrodes and including trenches overlapping the non-light emitting area; and a second insulating layer disposed between the first insulating layer and the anode electrodes, the second insulating layer including first openings respectively overlapping some of the trenches, and filling others of the trenches.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a block diagram illustrating a display device, according to an embodiment of the present disclosure.

FIG. 2 is a block diagram illustrating one of sub-pixels of FIG. 1, according to an embodiment.

FIG. 3 is a circuit diagram illustrating the sub-pixel of FIG. 2, according to an embodiment.

FIG. 4 is a top plan view illustrating a display panel of FIG. 1, according to an embodiment.

FIG. 5 is an exploded perspective view illustrating a portion of the display panel of FIG. 4.

FIG. 6 is a cross-sectional view illustrating a light emitting structure, according to an embodiment.

FIG. 7 is a cross-sectional view illustrating a light emitting structure, according to an embodiment.

FIG. 8 is a top plan view illustrating a pixel, according to an embodiment of the present disclosure.

FIG. 9 is a cross-sectional view taken along line I-I′ of FIG. 8.

FIG. 10 to FIG. 21 are cross-sectional views illustrating a method of manufacturing the display device, according to the embodiment of the present disclosure.

FIG. 22 is a block diagram of an electronic device according to an embodiment.

FIG. 23 shows schematic views of various embodiments of an electronic device.

### DETAILED DESCRIPTION OF THE EMBODIMENTS

The present disclosure may be variously modified and have various forms. Embodiments of the present disclosure will be illustrated and described in detail in the following specification and figures. This, however, the present disclosure is not necessarily limited by the specific embodiments set forth herein, and it is to be understood as embracing all embodiments that fall within the spirit and scope of the present disclosure including changes, equivalents, and substitutes.

Like reference numerals are used for like constituent elements in describing each drawing. While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like. Terms such as first, second, and the like may be used to describe various constituent elements, and are not necessarily to be interpreted as limiting these constituent elements. These terms may be used to differentiate one constituent element from another. For example, a first constituent element may be referred to as a second constituent element, and similarly, a second constituent element may be referred to as a first constituent element, without departing from the scope of the present disclosure.

In the present application, it should be understood that the term “include”, “comprise”, “have”, or “configure” indicates that a feature, a number, a step, an operation, a constituent element, a part, or a combination thereof described in the specification is present, but does not exclude a possibility of presence or addition of one or more other features, numbers, steps, operations, constituent elements, parts, or combinations, in advance. It will be understood that when an element such as a layer, film, region, area, or substrate is referred to as being “on” another element, it can be directly on the other element or intervening elements may also be present. In the present specification, when a portion of a layer, film, region, area, plate, or the like is referred to as being formed “on” another portion, the formed direction is not limited to an upper direction but includes a lateral or lower direction. In contrast, when an element of a layer, film, region, area, plate, or the like is referred to as being “below” another element, it may be directly below the other element, or intervening elements may be present.

In the description below, singular forms are to include plural forms unless the context clearly indicates only the singular.

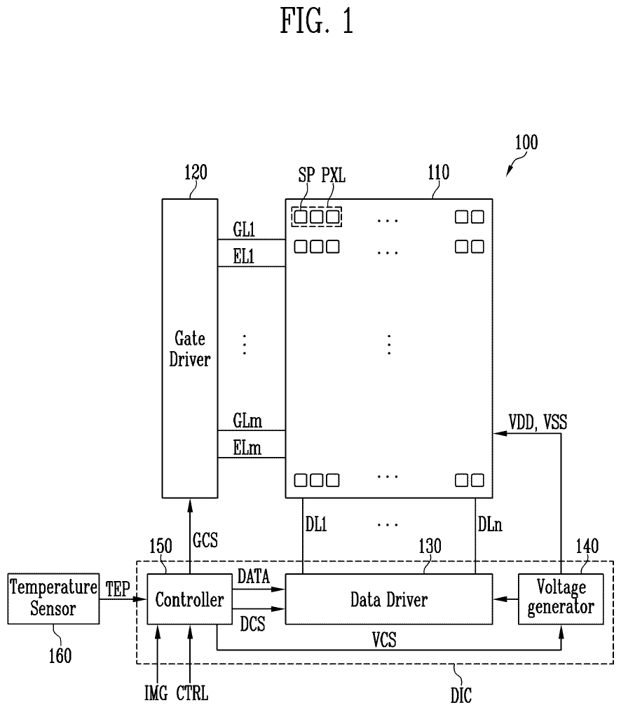

FIG. 1 illustrates a block diagram of a display device according to an embodiment of the present disclosure.

Referring to FIG. 1, a display device 100 may include a display panel 110, a gate driver 120, a data driver 130, a voltage generator 140, and a controller 150.

The display panel 110 includes sub-pixels SP. The sub-pixels SP may be connected to the gate driver 120 through first to m-th gate lines GL1 to GLm. The sub-pixels SP may be connected to the data driver 130 through first to n-th data lines DL1 to DLn. Here, m and n are positive integers.

Each of the sub-pixels SP may include at least one light emitting element configured to generate light. Accordingly, the sub-pixels SP may respectively generate light of a specific color, such as red, green, blue, cyan, magenta, yellow, or the like. Two or more of the sub-pixels SP may together be considered one pixel PXL. For example, as shown in FIG. 1, three sub-pixels may together form one pixel PXL.

The gate driver 120 is connected to the sub-pixels SP arranged in a row direction through the first to m-th gate lines GL1 to GLm. The gate driver 120 may output gate signals to the first to m-th gate lines GL1 to GLm in response to a gate control signal GCS. In the embodiment, the gate control signal GCS may include a start signal indicating the start of each frame, a horizontal synchronization signal for outputting gate signals in synchronization with the timing at which data signals are applied, and the like.

In the embodiment, first to m-th light emitting control lines EL1 to ELm connected to the sub-pixels SP in a row direction may be further provided. In this case, the gate driver 120 may include a light emitting control driver configured to control the first to m-th light emitting control lines EL1 to ELm, and the light emitting control driver may operate under the control of the controller 150.

The gate driver 120 may be disposed on one side of the display panel 110. However, embodiments are not necessarily limited thereto. For example, the gate driver 120 may be divided into two or more physically and/or logically separated drivers, and the drivers may be disposed on one side of the display panel 110 and the other side of the display panel 110 opposite to the one side. As described above, the gate driver 120 may be disposed around the display panel 110 in various forms according to the embodiments.

The data driver 130 is connected to the sub-pixels SP arranged in a column direction through the first to n-th data lines DL1 to DLn. The data driver 130 receives image data (DATA) and data control signal DCS from the controller 150. The data driver 130 operates in response to the data control signal DCS. In the embodiment, the data control signal DCS may include a source start pulse, a source shift clock, a source output enable signal, and the like.

The data driver 130 may use voltages from the voltage generator 140 to apply data signals having grayscale voltages corresponding to the image data (DATA) to the first to n-th data lines DL1 to DLn. When a gate signal is applied to each of the first to m-th gate lines GL1 to GLm, data signals corresponding to the image data DATA may be applied to the data lines DL1 to DLm. Accordingly, the corresponding sub-pixels SP may generate light corresponding to the data signals. Accordingly, an image is displayed on the display panel 110.

In the embodiment, the gate driver 120 and the data driver 130 may include complementary metal-oxide semiconductor (CMOS) circuit elements.

The voltage generator 140 may operate in response to a voltage control signal VCS from the controller 150. The voltage generator 140 is configured to generate a plurality of voltages and provide the generated voltages to constituent elements of the display device 100. For example, the voltage generator 140 may be configured to generate a plurality of voltages by receiving an input voltage from a source that is external with respect to the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level that is lower than the first power voltage VDD. In an embodiment, the first power voltage VDD or the second power voltage VSS may be provided by an external device of the display device 100.

In addition, the voltage generator 140 may generate various voltages. For example, the voltage generator 140 may generate an initialization voltage applied to the sub-pixels SP. For example, during a sensing operation to sense electrical characteristics of transistors and/or light emitting elements of the sub-pixels SP, a predetermined reference voltage may be applied to the first to n-th data lines DL1 to DLn, and the voltage generator 140 may generate the reference voltage.

The controller 150 controls various operations of the display device 100. The controller 150 receives input image data MG and a control signal CTRL for controlling the display of the input image data, from an external source. The controller 150 may provide the gate control signal GCS, the data control signal DCS, and the voltage control signal VCS in response to the control signal CTRL.

The controller 150 may convert the input image data IMG to be suitable for the display device 100 or the display panel 110 to output the image data DATA. In the embodiment, the controller 150 may output the image data DATA by aligning the input image data IMG to be suitable for the sub-pixels SP of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally separate components within one driver integrated circuit DIC. In an embodiment, the data driver 130, the voltage generator 140, and/or the controller 150 may be provided as a component separated from the driver integrated circuit DIC.

The display device 100 may include at least one temperature sensor 160. The temperature sensor 160 is configured to sense a surrounding temperature and generate temperature data TEP representing the sensed temperature. In the embodiment, the temperature sensor 160 may be adjacent to the display panel 110 and/or the driver integrated circuit DIC.

The controller 150 may control various operations of the display device 100 in response to the temperature data TEP. In the embodiment, the controller 150 may adjust the luminance of an image outputted from the display panel 110 in response to the temperature data TEP. For example, the controller 150 may control the data signals and the first and second power voltages VDD and VSS by controlling components such as the data driver 130 and/or the voltage generator 140.

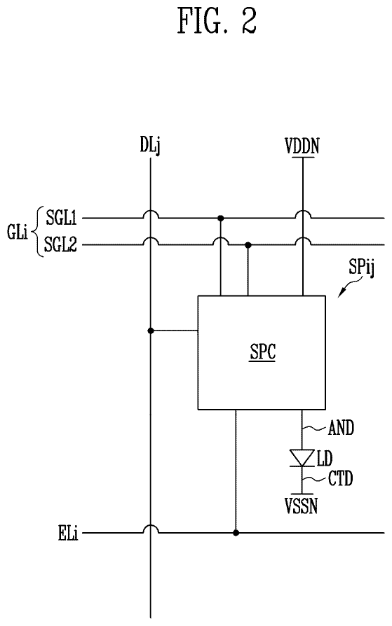

FIG. 2 is a block diagram illustrating one of sub-pixels of FIG. 1, according to an embodiment. In FIG. 2, among the sub-pixels SP of FIG. 1, a sub-pixel SPij disposed in an i-th row (here, i is an integer greater than or equal to 1 and less than or equal to m) and a j-th column (here, j is an integer greater than or equal to 1 and less than or equal to n) is illustrated as an example.

Referring to FIG. 2, the sub-pixel SPij may include a sub-pixel circuit SPC and a light emitting element LD.

The light emitting element LD is connected between the first power voltage node VDDN and a second power voltage node VSSN. In this case, the first power voltage node VDDDN is a node that transmits the first power voltage VDD of FIG. 1, and the second power voltage node VSSN is a node that transmits the second power voltage VSS of FIG. 1.

An anode electrode AND of the light emitting element LD may be connected to the first power voltage node VDDN through the sub-pixel circuit SPC, and a cathode electrode CTD of the light emitting element LD may be connected to the second power voltage node VSSN. For example, the anode electrode AND of the light emitting element LD may be connected to the first power voltage node VDDN through one or more transistors included in the sub-pixel circuit SPC.

The sub-pixel circuit SPC may be connected to an i-th gate line GLi among the first to m-th gate lines GL1 to GLm of FIG. 1, an i-th light emitting control line ELi among the first to m-th light emitting control lines EL1 to ELm of FIG. 1, and a j-th data line DLj among the first to n-th data lines DL1 to DLn of FIG. 1. The sub-pixel circuit SPC is configured to control the light emitting element LD according to signals received through these signal lines.

The sub-pixel circuit SPC may operate in response to a gate signal received through the i-th gate line GLi. The i-th gate line GLi may include one or more sub-gate lines. In the embodiment, as shown in FIG. 2, the i-th gate line GLi may include first and second sub-gate lines SGL1 and SGL2. The sub-pixel circuit SPC may operate in response to gate signals received through the first and second sub-gate lines SGL1 and SGL2. As such, when the i-th gate line GLi includes two or more sub-gate lines, the sub-pixel circuit SPC may operate in response to gate signals received through the corresponding sub-gate lines.

The sub-pixel circuit SPC may operate in response to a light emitting control signal received through the i-th light emitting control line ELi. In the embodiment, the i-th light emitting control line ELi may include one or more sub-light emitting control lines. When the i-th light emitting control line ELi includes two or more sub-light emitting control lines, the sub-pixel circuit SPC may operate in response to light emitting control signals received through the corresponding sub-light emitting control lines.

The sub-pixel circuit SPC may receive a data signal through the j-th data line DLj. The sub-pixel circuit SPC may store a voltage corresponding to the data signal in response to the gate signals received through the first and/or second sub-gate lines SGL1 and SGL2. In response to the light emitting control signal received through the i-th light emitting control line ELi, the sub-pixel circuit SPC may adjust the current flowing from the first power voltage node VDDN to the second power voltage node VSSN through the light emitting element LD according to the stored voltage. Accordingly, the light emitting element LD may generate light of luminance corresponding to the data signal.

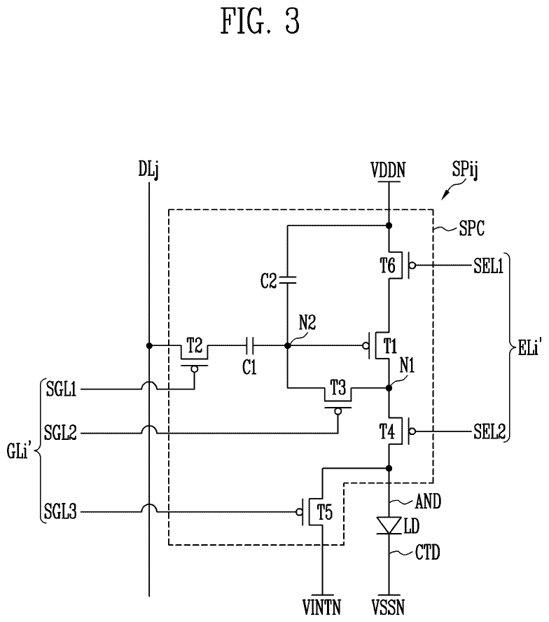

FIG. 3 is a circuit diagram illustrating the sub-pixel of FIG. 2, according to an embodiment.

Referring to FIG. 3, the sub-pixel SPij may include a sub-pixel circuit SPC and a light emitting element LD.

The sub-pixel circuit SPC may be connected to an i-th gate line GLi′, an i-th light emitting control line ELi′, and a j-th data line DLj. Compared to the i-th gate line GLi of FIG. 2, the i-th gate line GLi′ may further include a third sub-gate line SGL3. Compared to the i-th light emitting control line ELi of FIG. 2, the i-th light emitting control line ELi′ may include a first sub-light emitting control line SEL1 and a second sub-light emitting control line SEL2.

The sub-pixel circuit SPC may include the first to sixth transistors T1 to T6 and the first and second capacitors C1 and C2.

The first transistor T1 is connected between the first power voltage node VDDN and a first node N1. A gate of the first transistor T1 is connected to a second node N2, and accordingly, the first transistor T1 may be turned on according to a voltage level of the second node N2. The first transistor T1 may be referred to as a driving transistor.

The second transistor T2 is connected between the j-th data line DLj and the second node N2. A gate of the second transistor T2 is connected to the first sub-gate line SGL1, and accordingly, the second transistor T2 may be turned on in response to the gate signal of the first sub-gate line SGL1. The second transistor T2 may be referred to as a switching transistor.

The third transistor T3 is connected between the first node N1 and the second node N2. A gate of the third transistor T3 is connected to the second sub-gate line SGL2, and accordingly, the third transistor T3 may be turned on in response to the gate signal of the second sub-gate line SGL2.

The fourth transistor T4 is connected between the first node N1 and the anode electrode AND of the light emitting element LD. A gate of the fourth transistor T4 is connected to the second sub-light emitting control line SEL2, and accordingly, the fourth transistor T4 may be turned on in response to the light emitting control signal of the second sub-light emitting control line SEL2.

The fifth transistor T5 is connected between the anode electrode AND of the light emitting element LD and an initialization voltage node VINTN. The initialization voltage node VINTN is configured to transmit an initialization voltage. In the embodiment, the initialization voltage may be provided by the voltage generator 140 of FIG. 1. In an embodiment, the initialization voltage may be provided by an external device to the display device 100. Agate of the fifth transistor T5 is connected to the third sub-gate line SGL3, and accordingly, the fifth transistor T5 may be turned on in response to the gate signal of the third sub-gate line SGL3.

The sixth transistor T6 is connected between a first power voltage node VDDN and the first transistor T1. A gate of the sixth transistor T6 is connected to the first sub-light emitting control line SEL1, and accordingly, the sixth transistor T6 may be turned on in response to the light emitting control signal of the first sub-light emitting control line SEL1.

The first capacitor C1 is connected between the second transistor T2 and the second node N2. The second capacitor C2 is connected between the first power voltage node VDDN and the second node N2.

As described above, the sub-pixel circuit SPC may include the first to sixth transistors T1 to T6 and the first and second capacitors C1 and C2. However, embodiments are not necessarily limited thereto. The sub-pixel circuit SPC may be implemented as one of various circuits including a plurality of transistors and one or more capacitors. For example, the sub-pixel circuit SPC may include two transistors and one capacitor. According to the embodiments of the sub-pixel circuit SPC, the number of sub-gate lines included in the i-th gate line GLi′ and the number of sub-light emitting control lines included in the i-th light emitting control line ELi′ may vary.

The first to sixth transistors T1 to T6 may be P-type transistors. Each of the first to sixth transistors T1 to T6 may be a metal oxide silicon field effect transistor (MOSFET). However, embodiments are not necessarily limited thereto. For example, at least one of the first to sixth transistors T1 to T6 may be replaced with an N-type transistor.

In the embodiment, the first to sixth transistors T1 to T6 may include an amorphous silicon semiconductor, a monocrystalline silicon semiconductor, a polycrystalline silicon semiconductor, and an oxide semiconductor.

The light emitting element LD may include the anode electrode AND, the cathode electrode CTD, and the light emitting layer. The light emitting layer may be disposed between the anode electrode AND and the cathode electrode CTD. After the data signal transmitted through the j-th data line DLj is reflected in the voltage of the second node N2, the fourth and sixth transistors T4 and T6 may be turned on when the light emitting control signals of the first and second sub-light emitting control lines SEL1 and SEL2 are enabled to a low level. In addition, the first transistor T1 may be turned on according to the voltage of the second node N2, and accordingly, a current may flow from the first power voltage node VDDN to the second power voltage node VSSN. The light emitting element LD may emit light depending on the amount of current flowing.

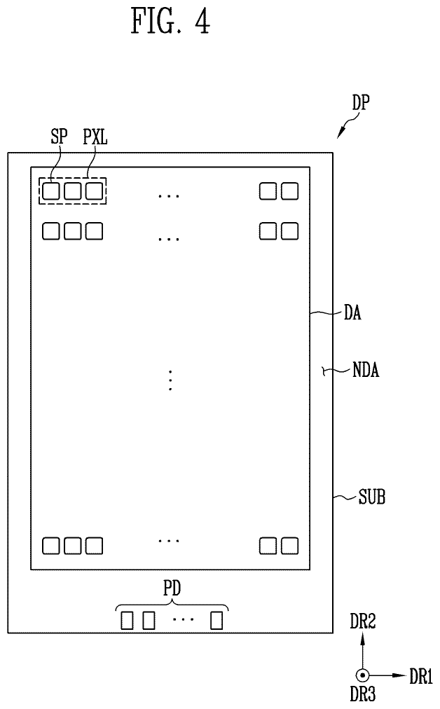

FIG. 4 is a top plan view illustrating a display panel of FIG. 1 according to an embodiment.

Referring to FIG. 4, an embodiment DP of the display panel 110 of FIG. 1 may include a display area DA and a non-display area NDA. The display panel DP displays an image through the display area DA. The non-display area NDA is disposed around the display area DA.

The display panel DP may include a substrate SUB, sub-pixels SP, and pads PD.

The sub-pixels SP are disposed in the display area DA on the substrate SUB. The sub-pixels SP may be arranged in a matrix format along a first direction DR1 and a second direction DR2 that intersects the first direction DR1. However, embodiments are not necessarily limited thereto. For example, the sub-pixels SP may be arranged in a zigzag form along first direction DR1 and second direction DR2. For example, the sub-pixels SP may be disposed in a PENTILE™ shape, where PENTILE™ is an arrangement of luminous areas manufactured by SAMSUNG. The first direction DR1 may be a row direction, and the second direction DR2 may be a column direction.

Two or more of the plurality of sub-pixels SP may form one pixel PXL.

A constituent element to control the sub-pixels SP may be disposed in the non-display area NDA on the substrate SUB. For example, wires connected to the sub-pixels SP, such as the first to m-th gate lines GL1 to GLm and the first to n-th data lines DL1 to DLn of FIG. 1, may be disposed in the non-display area NDA.

The gate driver 120, the data driver 130, the voltage generator 140, the controller 150, and/or the temperature sensor 160 in FIG. 1 may be integrated in the non-display area NDA of the display panel DP. In the embodiment, the gate driver 120 of FIG. 1 may be mounted on the display panel DP, and may be disposed in the non-display area NDA. In an embodiment, the gate driver 120 may be implemented as an integrated circuit separated from the display panel DP. In the embodiment, the temperature sensor 160 may be disposed in the non-display area NDA to detect the temperature of the display panel DP.

The pads PD are disposed in the non-display area NDA on the substrate SUB. The pads PD may be electrically connected to the sub-pixels SP through wires. For example, the pads PD may be connected to the sub-pixels SP through the first to n-th data lines DL1 to DLn.

The pads PD may interface the display panel DP to other constituent elements of the display device 100 (see FIG. 1). In the embodiment, voltages and signals required for operations of constituent elements included in the display panel DP may be provided from the driver integrated circuit DIC of FIG. 1 through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. For example, when the gate driver 120 is mounted on the display panel DP, the gate control signal GCS may be transmitted from the driver integrated circuit DIC to the gate driver 120 through the pads PD.

In the embodiment, the circuit board may be electrically connected to the pads PD by using a conductive adhesive such as an anisotropic conductive film. In this case, the circuit board may be a flexible printed circuit board (FPCB) or a flexible film made of a flexible material. The driver integrated circuit DIC may be mounted on the circuit board to be electrically connected to the pads PD.

In the embodiment, the display area DA may have various shapes. The display area DA may have a closed-loop shape including sides of a straight line and/or a curved line. For example, the display area DA may have shapes such as a polygonal shape, a circular shape, a semicircular, and an elliptical shape.

In the embodiment, the display panel DP may have a flat display surface. In an embodiment, the display panel DP may have a display surface that is at least partially round. In the embodiment, the display panel DP may be bendable, foldable, or rollable. In these cases, the display panel DP and/or the substrate SUB may include materials with flexible properties.

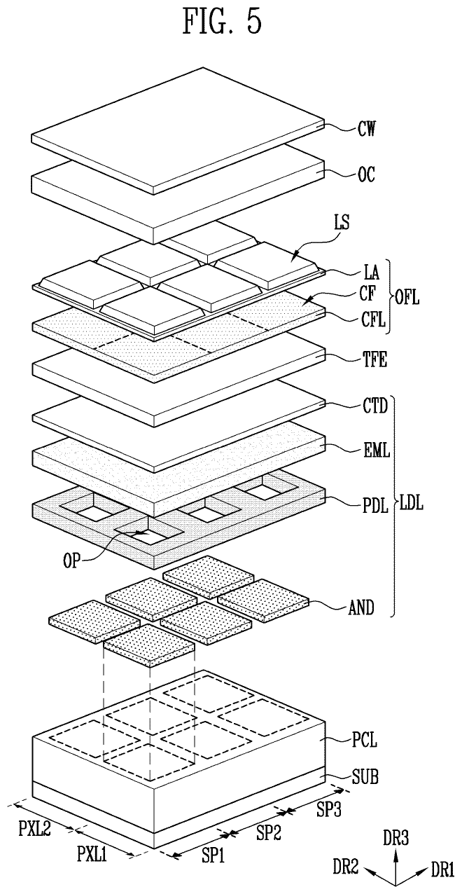

FIG. 5 is an exploded perspective view illustrating a portion of the display panel of FIG. 4. In FIG. 5, for clear and concise description, a portion of the display panel DP corresponding to two pixels PXL1 and PXL2 among the pixels PXL of FIG. 4 is schematically shown. Portions of the display panel DP corresponding to the remaining pixels may be similarly configured.

Referring to FIG. 4 and FIG. 5, each of the first and second pixels PXL1 and PXL2 may include first to third sub-pixels SP1 to SP3. However, embodiments are not necessarily limited thereto. For example, each of the first and second pixels PXL1 and PXL2 may include four sub-pixels, or two sub-pixels.

In FIG. 5, the first to third sub-pixels SP1 to SP3 is illustrated to have quadrilateral shapes and have the same sizes when viewed in the third direction DR3 crossing the first and second directions DR1 and DR2. However, embodiments are not necessarily limited thereto. The first to third sub-pixels SP1 to SP3 may be modified to have various shapes.

The display panel DP may include a substrate SUB, a pixel circuit layer PCL, a light emitting element layer LDL, an encapsulation layer TFE, an optical functional layer OFL, an overcoat layer OC, and a cover window CW.

The substrate SUB may be made of an insulating material such as glass or a resin. For example, the substrate SUB may include a glass substrate. As an example, the substrate SUB may include a polyimide (PI) substrate. For example, the substrate SUB may include a silicon wafer substrate formed using a semiconductor process.

In the embodiment, the substrate SUB may be made of a flexible material to be bendable or foldable, and may have a single-layered structure or a multi-layered structure. For example, the flexible material may include polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and/or cellulose acetate propionate. However, embodiments are not necessarily limited thereto.

The pixel circuit layer PCL is disposed on the substrate SUB. The substrate SUB and/or the pixel circuit layer PCL may include insulating layers and conductive patterns disposed between the insulating layers. The conductive patterns of the pixel circuit layer PCL may function as at least some of circuit elements, wires, and the like

The conductive patterns may include copper, but embodiments are not necessarily limited thereto.

The circuit elements may include the sub-pixel circuit SPC (see FIG. 2) for each of first to third sub-pixels SP1 to SP3. The sub-pixel circuit SPC may include transistors and one or more capacitors. Each transistor may include a semiconductor portion including a source area, a drain area, and a channel area, and a gate electrode overlapping the semiconductor portion. In the embodiment, when the substrate SUB is provided as a silicon substrate, the semiconductor portion may be included in the substrate SUB, and the gate electrode may be included in the pixel circuit layer PCL as the conductive pattern of the pixel circuit layer PCL. In the embodiment, when the substrate SUB is provided as a glass substrate or a PI substrate, the semiconductor portion and the gate electrode may be included in the pixel circuit layer PCL. Each capacitor may include electrodes spaced apart from each other. For example, each capacitor may include electrodes spaced apart from each other on a plane defined by the first and second directions DR1 and DR2. For example, each capacitor may include electrodes spaced apart from each other in the third direction DR3 with an insulating layer therebetween.

The wires of the pixel circuit layer PCL may include signal lines connected to each of the first to third sub-pixels SP1 to SP3, for example, a gate line, a light emitting control line, and a data line. The wires may further include the wire connected to the first power voltage node VDDN of FIG. 2. In addition, the wires may further include the wire connected to the second power voltage node VSSN of FIG. 2.

The light emitting element layer LDL may include anode electrodes AND, a pixel defining film PDL, a light emitting layer EML, and a cathode electrode CTD.

The anode electrodes AND may be disposed on the pixel circuit layer PCL. The anode electrodes AND may contact circuit elements of the pixel circuit layer PCL. The anode electrodes AND may include an opaque conductive material capable of reflecting light, but embodiments are not necessarily limited thereto.

The pixel defining film PDL is disposed on the anode electrodes AND. The pixel defining film PDL may include an opening OP exposing a portion of each of the anode electrodes AND. The opening OP of the pixel defining film PDL may be understood as light emitting areas corresponding to the first to third sub-pixels SP1 to SP3, respectively.

In the embodiment, the pixel defining film PDL may include an inorganic material. In this case, the pixel defining film PDL may include a plurality of stacked inorganic layers. For example, the pixel defining film PDL may include a silicon oxide (SiOx) and a silicon nitride (SiNx). In an embodiment, the pixel defining film PDL may include an organic material. However, the material of the pixel defining film PDL is not necessarily limited thereto.

The light emitting layer EML may be disposed on the anode electrodes AND exposed by the opening OP of the pixel defining film PDL. The light emitting layer EML may include an organic light emitting layer configured to generate light, an electron transport layer configured to transport electrons, and a hole transport layer configured to transport holes.

In the embodiment, the light emitting layer EML may fill the opening OP of the pixel defining film PDL, and may be disposed entirely on an upper portion of the pixel defining film PDL. For example, the light emitting layer EML may extend across the first to third sub-pixels SP1 to SP3. In this case, at least some of the functional layers in the light emitting layer EML may be disconnected or bent at the boundaries between the first to third sub-pixels SP1 to SP3. However, embodiments are not necessarily limited thereto. For example, portions of the light emitting layer EML corresponding to the first to third sub-pixels SP1 to SP3 are partially separated from each other, and each of them may overlap the opening OP of the pixel defining film PDL.

The cathode electrode CTD may be disposed on the light emitting layer EML. The cathode electrode CTD may extend across the first to third sub-pixels SP1 to SP3. As such, the cathode electrode CTD may be provided as a common electrode for the first to third sub-pixels SP1 to SP3. The cathode electrode CTD may also be disconnected or bent at boundaries between the first to third sub-pixels SP1 to SP3, like the light emitting layer EML.

The cathode electrode CTD may be a thin metal layer with a thickness that is sufficient to transmit light emitted from the light emitting layer EML. The cathode electrode CTD may be made of a metallic material or a transparent conductive material and may be relatively thin. In the embodiment, the cathode electrode CTD may include various transparent conductive materials including an indium tin oxide, an indium zinc oxide, an indium tin zinc oxide, an aluminum zinc oxide, a gallium zinc oxide, a zinc tin oxide, and/or a gallium tin oxide. In an embodiment, the cathode electrode CTD may include silver (Ag), and/or magnesium (Mg). However, the material of the cathode electrode CTD is not necessarily limited thereto.

One of the anode electrodes AND, the portion of the light emitting layer EML overlapping it, and the portion of the cathode electrode CTD overlapping it may be understood to configure one light emitting element LD (see FIG. 2). For example, each of the light emitting elements of the first to third sub-pixels SP1 to SP3 may include one anode electrode, a portion of the light emitting layer EML overlapping it, and a portion of the cathode electrode CTD overlapping it. In each of the first to third sub-pixels SP1 to SP3, holes injected from the anode electrode AND and electrons injected from the cathode electrode CTD are transported into the light emitting layer of the light emitting layer EML to form excitons, and when the excitons transition from the excited state to the ground state, light may be generated. The luminance of light may be determined depending on the amount of current flowing through the light emitting layer. Depending on the configuration of the light emitting layer, the wavelength range of the generated light may be determined.

The encapsulation layer TFE is disposed on the cathode electrode CTD. The encapsulation layer TFE may cover the light emitting element layer LDL and/or the pixel circuit layer PCL. The encapsulation layer TFE may be configured to prevent oxygen and/or moisture from penetrating into the light emitting element layer LDL. In the embodiment, the encapsulation layer TFE may include a structure in which one or more inorganic films and one or more organic films are alternately stacked. For example, the inorganic film may include a silicon nitride, a silicon oxide, or a silicon oxynitride (SiOxNy). For example, the organic film may include an organic insulating material such as an acrylic resin, an epoxy resin, a phenol resin, a polyamide resin, a polyimide resin, an unsaturated polyesters resin, a polyphenylenethers resin, a polyphenylenesulfides resin, or a benzocyclobutene. However, the materials of the organic film and the inorganic film of the encapsulation layer TFE are not necessarily limited thereto.

The encapsulation layer TFE may further include a thin film containing an aluminum oxide (AlOx) to increase the encapsulation efficiency of the encapsulation layer TFE. The thin film containing an aluminum oxide may be disposed on the upper surface of the encapsulation layer TFE facing the optical functional layer OFL and/or the lower surface of the encapsulation layer TFE facing the light emitting element layer LDL.

The thin film containing the aluminum oxide may be formed through atomic layer deposition (ALD). However, embodiments are not necessarily limited thereto. The encapsulation layer TFE may further include a thin film made of various materials suitable for increasing the encapsulation efficiency.

The optical functional layer OFL is disposed on the encapsulation layer TFE. The optical function layer OFL may include a color filter layer CFL and a lens array LA.

The color filter layer CFL is disposed between the encapsulation layer TFE and the lens array LA. The color filter layer CFL is configured to selectively output light in a wavelength range or color corresponding to each sub-pixel by filtering light emitted from the light emitting layer EML. The color filter layer CFL includes color filters CF respectively corresponding to the first to third sub-pixels SP1 to SP3), and each of the color filters CF may pass light in a wavelength range corresponding to the sub-pixel. For example, a color filter corresponding to the first sub-pixel SP1 may pass red light, a color filter corresponding to the second sub-pixel SP2 may pass green light, and a color filter corresponding to the third sub-pixel SP3 may pass blue light. At least some of the color filters CF may be omitted according to light emitted from the light emitting layer EML of each sub-pixel.

The lens array LA is disposed on the color filter layer CFL. The lens array LA may include lenses LS respectively corresponding to the first to third sub-pixels SP1 to SP3. Each of the lenses LS may increase light output efficiency by outputting light emitted from the light emitting layer EML in an intended path. The lens array LA may have a relatively high refractive index. For example, the lens array LA may have a higher refractive index than the overcoat layer OC. In the embodiment, lenses LS may include an organic material. In the embodiment, the lenses LS may include an acrylic material. However, the material of the lenses LS is not necessarily limited thereto.

In the embodiment, compared to the opening OP of the pixel defining film PDL, at least some of the color filters CF of the color filter layer CF and at least some of the lenses LS of the lens array LA may be shifted in a direction parallel to a plane defined by the first and second directions DR1 and DR2. For example, in the center area of the display area DA, the center of the color filter and the center of the lens may be aligned or overlapped with the center of the opening OP of the corresponding pixel defining film PDL when viewed in the third direction DR3. For example, in the central area of the display area DA, the opening OP of the pixel defining film PDL may completely overlap the corresponding color filter of the color filter layer CF and the corresponding lens of the lens array LA. In an area of the display area DA adjacent to the non-display area NDA, the center of the color filter and the center of the lens may be shifted in a planar direction from the center of the opening OP of the corresponding pixel defining film PDL when viewed in the third direction DR3. For example, in an area of the display area DA adjacent to the non-display area NDA, the opening OP of the pixel defining film PDL may partially overlap the corresponding color filter of the color filter layer CFL and the corresponding lens of the lens array LA. Accordingly, in the center of the display area DA, light emitted from the light emitting layer EML may be efficiently outputted in the normal direction of the display surface. Light emitted from the light emitting layer EML at the outside of the display area DA may be efficiently outputted in a direction inclined by a predetermined angle with respect to the normal direction of the display surface.

The overcoat layer OC may be disposed on the lens array LA. The overcoat layer OC may cover the optical functional layer OFL, the encapsulation layer TFE, the light emitting layer EML, and/or the pixel circuit layer PCL. The overcoat layer OC may include various materials suitable for protecting lower layers thereof from foreign substances such as dust and moisture. For example, the overcoat layer OC may include an inorganic insulating film and/or an organic insulating film. For example, the overcoat layer OC may include an epoxy resin, but embodiments are not necessarily limited thereto. The overcoat layer OC may have a lower refractive index than the lens array LA.

The cover window CW may be disposed on the overcoat layer OC. The cover window CW is configured to protect lower layers thereof. The cover window CW may have a higher refractive index than the overcoat layer OC. The cover window CW may include glass, but embodiments are not necessarily limited thereto. For example, the cover window CW may be an encapsulation glass configured to protect constituent elements disposed thereunder. In an embodiment, the cover window CW may be omitted.

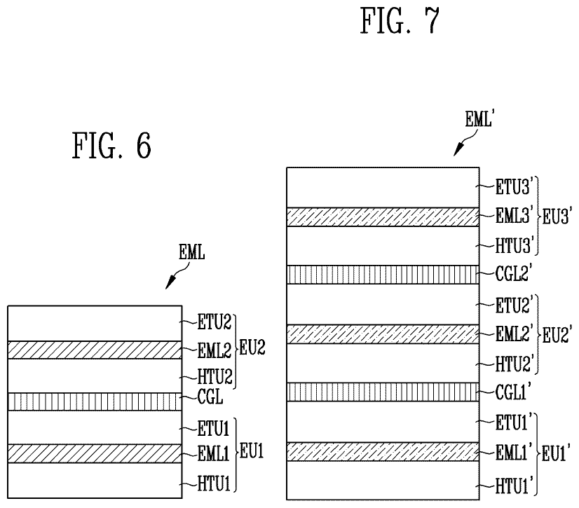

FIG. 6 is a cross-sectional view illustrating a light emitting structure, according to an embodiment.

Referring to FIG. 6, the light emitting layer EML may have a tandem structure in which first and second light emitting portions EU1 and EU2 are stacked.

Each of the first and second light emitting portions EU1 and EU2 may include at least one light emitting layer that generates light according to a current applied thereto. The first light emitting portion EU1 may include a first light emitting layer EML1, a first electron transport portion ETU1, and a first hole transport portion HTU1. The first light emitting layer EML1 may be disposed between the first electron transport portion ETU1 and the first hole transport portion HTU1. The second light emitting portion EU2 may include a second light emitting layer EML2, a second electron transport portion ETU2, and a second hole transport portion HTU2. The second light emitting layer EML2 may be disposed between the second electron transport portion ETU2 and the second hole transport portion HTU2.

Each of the first and second hole transport portions HTU1 and HTU2 may include a hole injection layer and/or a hole transport layer, and may further include a hole buffer layer, an electron blocking layer, or the like as needed. The first and second hole transport portions HTU1 and HTU2 may have the same configuration or different configurations.

Each of the first and second electron transport portions ETU1 and ETU2 may include an electron injection layer and/or an electron transport layer, and may further include an electron buffer layer and a hole blocking layer as needed. The first and second electron transport portions ETU1 and ETU2 may have the same configuration or different configurations.

A connection layer, which may be provided in the form of a charge generation layer CGL, may be disposed between the first light emitting portion EU1 and the second light emitting portion EU2 to connect them to each other. In the embodiment, the charge generation layer CGL may have a stacked structure of a p dopant layer and an n dopant layer. For example, the p dopant layer may include a p-type dopant such as HAT-CN, TCNQ, and NDP-9, and the n dopant layer may include an alkali metal, an alkaline earth metal, a lanthanide-based metal, or a combination thereof. However, embodiments are not necessarily limited thereto.

In the embodiment, the first light emitting layer EML1 and the second light emitting layer EML2 may generate light of different colors. The light emitted from each of the first light emitting layer EML1 and the second light emitting layer EML2 may be mixed to be recognized as white light. For example, the first light emitting layer EML1 may generate blue-colored light, and the second light emitting layer EML2 may generate yellow-colored light. In the embodiment, the second light-emitting layer EML2 may include a structure in which a first sub-light-emitting layer configured to generate red-colored light and a second sub-light-emitting layer configured to generate green-colored light are stacked. The red-colored light and the green-colored light may be mixed to provide yellow-colored light. In this case, an intermediate layer configured to perform a function of transporting holes and/or preventing transport of electrons may be further disposed between the first and second sub-light emitting layers.

In an embodiment, the first light emitting layer EML1 and the second light emitting layer EML2 may generate light of the same color.

The light emitting layer EML may be formed through a vacuum deposition method, an inkjet printing method, or the like, but embodiments are not necessarily limited thereto.

FIG. 7 is a cross-sectional view illustrating a light emitting structure according to an embodiment.

Referring to FIG. 7, a light emitting layer EML′ may have a tandem structure in which first to third light emitting portions EU1′ to EU3′ are stacked.

Each of the first to third light emitting portions EU1′ to EU3′ may include a light emitting layer that generates light according to a current applied thereto. The first light emitting portion EU1′ may include a first light emitting layer EML1′, a first electron transport portion ETU1′, and a first hole transport portion HTU1′. The first light emitting layer EML1′ may be disposed between the first electron transport portion ETU1′ and the first hole transport portion HTU1′. The second light emitting portion EU2′ may include a second light emitting layer EML2′, a second electron transport portion ETU2′, and a second hole transport portion HTU2′. The second light emitting layer EML2′ may be disposed between the second electron transport portion ETU2′ and the second hole transport portion HTU2′. The third light emitting portion EU3′ may include a third light emitting layer EML3′, a third electron transport portion ETU3′, and a third hole transport portion HTU3′. The third light emitting layer EML3′ may be disposed between the third electron transport portion ETU3′ and the third hole transport portion HTU3′.

Each of the first to third hole transport portions HTU1′ to HTU3′ may include a hole injection layer and/or a hole transport layer, and may further include a hole buffer layer, an electron blocking layer, or the like as needed. The first to third hole transport portions HTU1′ to HTU3′ may have the same configuration or different configurations.

Each of the first to third electron transport portions ETU1′ to ETU3′ may include an electron injection layer and/or an electron transport layer, and may further include an electron buffer layer and a hole blocking layer as needed. The first to third electron transport portions ETU1′ to ETU3′ may have the same configuration or different configurations.

A first charge generation layer CGL1′ is disposed between the first light emitting portion EU1′ and the second light emitting portion EU2′. A second charge generation layer CGL2′ is disposed between the second light emitting portion EU2′ and the third light emitting portion EU3′.

In the embodiment, the first to third light emitting layers EML1′ to EML3′ may generate light of different colors. Light emitted from each of the first to third light emitting layers EML1′ to EML3′ may be mixed to be viewed as white light. For example, the first light emitting layer EML1′ may generate light of a blue color, the second light emitting layer EML2′ may generate light of a green color, and the third light emitting layer EML3′ may generate light of a red color.

In an embodiment, two or more of the first to third light emitting layers EML1′ to EML3′ may generate light of the same color.

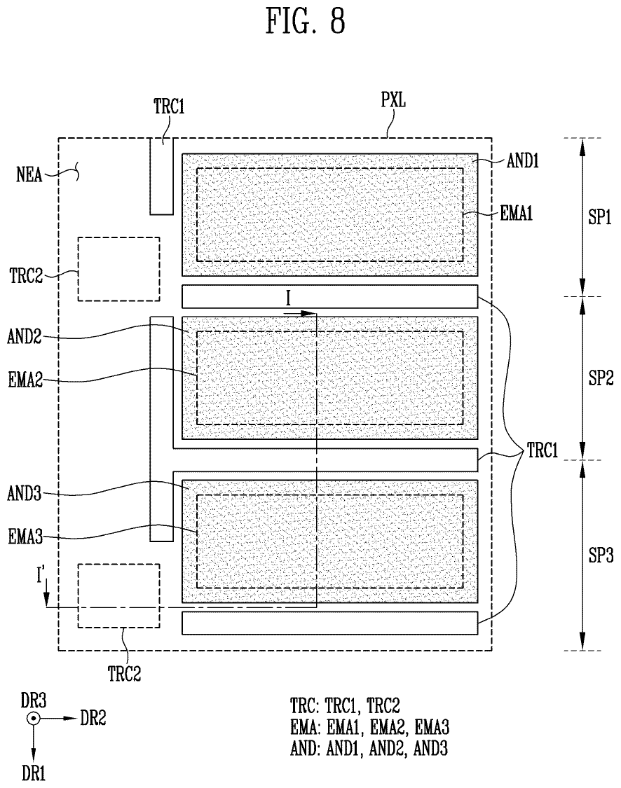

FIG. 8 is a top plan view illustrating a pixel according to an embodiment of the present disclosure.

For convenience of illustration, only the anode electrodes AND, first trenches TRC1, and second trenches TRC2 are shown in FIG. 8.

Referring to FIG. 8, the pixel PXL may include the first to third sub-pixels SP1 to SP3 disposed in the first direction DR1. The pixel PXL may include light emitting areas EMA and non-light emitting areas NEA surrounding the light emitting areas EMA.

The first sub-pixel SP1 may include a first light emitting area EMA1 and a non-light emitting area NEA surrounding the first light emitting area EMA1. The second sub-pixel SP2 may include a second light emitting area EMA2 and a non-light emitting area NEA surrounding the second light emitting area EMA2. The third sub-pixel SP3 may include a third light emitting area EMA3 and a non-light emitting area NEA surrounding the third light emitting area EMA3.

The first light emitting area EMA1 may be an area in which light is emitted from a portion of the light emitting layer EML (see FIG. 5) corresponding to the first sub-pixel SP1. The second light emitting area EMA2 may be an area in which light is emitted from a portion of the light emitting layer EML corresponding to the second sub-pixel SP2. The third light emitting area EMA3 may be an area in which light is emitted from a portion of the light emitting layer EML corresponding to the third sub-pixel SP3.

A first anode electrode AND1 may be disposed in the first light emitting area EMA1. A second anode electrode AND2 may be disposed in the second light emitting area EMA2. A third anode electrode AND3 may be disposed in the third light emitting area EMA3.

In the embodiment, the pixel PXL may include trenches TRC overlapping the non-light emitting area NEA. The trenches TRC may include first and second trenches TRC1 and TRC2.

The first trenches TRC1 may be defined between adjacent anode electrodes AND. For example, the first trenches TRC1 may be defined between adjacent light emitting areas EMA. The first trenches TRC1 may be disposed not only between the light emitting areas EMA in one pixel PXL but also between adjacent pixels PXL.

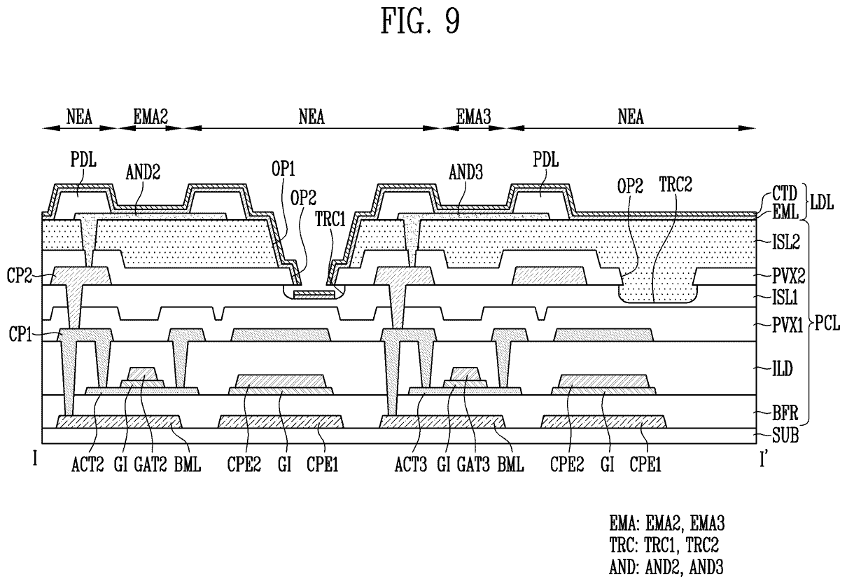

The first trenches TRC1 may extend in the first direction DR1 or the second direction DR2 between the light emitting areas EMA. For example, the first trenches TRC1 and the light emitting areas EMA may entirely overlap each other in the first direction DR1. The first trenches TRC1 are disposed between adjacent light emitting areas EMA and entirely overlap the light emitting areas EMA in the first direction DR1, so that the light emitting layer EML (see FIG. 9) disposed on the anode electrodes AND may be entirely disconnected between the adjacent light emitting areas EMA.

The second trenches TRC2 may be spaced apart from the anode electrodes AND and the first trenches TRC1 in a plan view. Unlike the first trenches TRC1, the second trenches TRC2 are not configured to disconnect the light emitting layer EML, so they may have various shapes.

In FIG. 8, each of the first to third light emitting areas EMA1 to EMA3 is indicated by a dashed box defined along the edge of the anode electrode overlapping each of the first to third light emitting areas EMA1 to EMA3.

For example, a pixel defining film may cover edges of the first to third anode electrodes AND1 to AND3, and portions of the first to third anode electrodes AND1 to AND3 that are not covered by the pixel defining film may be understood as the first to third light emitting areas EMA1 to EMA3. However, embodiments according to the present disclosure are not necessarily limited thereto. For example, it may be understood that the first to third light emitting areas EMA1 to EMA3 are defined by the first trenches TRC1. For example, the first to third light emitting areas EMA1 to EMA3 may be divided by the first trenches TRC1, and the non-light emitting area NEA may overlap the first trenches TRC1. The first light emitting area EMA1 may be defined by at least one first trench TRC1 disposed between the first anode electrode AND1 and anode electrodes adjacent thereto (for example, the third anode electrode AND3 and the second anode electrode AND2 adjacent to each other of another pixel). The second light emitting area EMA2 may be defined by at least one first trench TRC1 disposed between the second anode electrode AND2 and anode electrodes adjacent thereto (for example, the first anode electrode AND1 and the third anode electrode AND3). The third light emitting area EMA3 may be defined by at least one first trench TRC1 disposed between the third anode electrode AND3 and anode electrodes adjacent thereto (for example, the second anode electrode AND2, and the adjacent first anode electrode AND1 of another pixel). For another example, each of the first to third light emitting areas EMA1 to EMA3 may be defined as an area in which an anode electrode AND corresponding to each of the first to third light emitting areas EMA1 to EMA3 is disposed.

As such, the first to third light emitting areas EMA1 to EMA3 may be defined in various ways. Hereinafter, for better understanding and ease of description, the first to third light emitting areas EMA1 to EMA3 are described as being defined by portions of the first to third anode electrodes AND1 to AND3 that are not covered by the pixel defining film, respectively.

FIG. 9 illustrates a cross-sectional view taken along line I-I′ of FIG. 8.

Referring to FIG. 8 and FIG. 9, the pixel circuit layer PCL may be disposed on the substrate SUB. The pixel circuit layer PCL may include back metal layers BML, first capacitor electrodes CPE1, a buffer layer BFR, a second active electrode ACT2, a third active electrode ACT3, gate insulating layers GI, a second gate electrode GAT2, a third gate electrode GAT3, second capacitor electrodes CPE2, an interlayer insulating layer ILD, a first connection electrodes CP1, a first passivation layer PVX1, a first insulating layer ISL1, second connection electrodes CP2, a second passivation layer PVX2, and a second insulating layer ISL2.

The back metal layers BML and the first capacitor electrodes CPE1 may be disposed on the substrate SUB. The buffer layer BFR may be disposed on the substrate SUB, covering the back metal layers BML and the first capacitor electrodes CPE1.

The second active electrode ACT2 and the third active electrode ACT3 may be disposed on the buffer layer BFR. The gate insulating layer GI may be disposed on each of the second active electrode ACT2 and the third active electrode ACT3. The gate insulating layer GI may have an island shape. The second gate electrode GAT2 may be disposed on the gate insulating layer GI on the second active electrode ACT2. The second active electrode ACT2 and the second gate electrode GAT2 may form a second transistor. The third gate electrode GAT3 may be disposed on the gate insulating layer GI on the third active electrode ACT3. The third active electrode ACT3 and the third gate electrode GAT3 may form a third transistor.

The gate insulating layers GI may be further disposed on the buffer layer BFR. The second capacitor electrodes CPE2 may be disposed on the gate insulating layers GI, respectively. The second capacitor electrodes CPE2 overlap the first capacitor electrodes CPE1, respectively, and may form a capacitor.

The interlayer insulating layer ILD may be disposed on the buffer layer BFR, covering the second active electrode ACT2, the third active electrode ACT3, the second capacitor electrodes CPE2, the gate insulating layers GI, the second gate electrode GAT2, and the third gate electrode GAT3.

The first connection electrodes CP1 may be disposed on the interlayer insulating layer ILD. The first connection electrodes CP1 may be connected to the second active electrode ACT2, the third active electrode ACT3, and the back metal layers BML, which are disposed thereunder. The first passivation layer PVX1 may be disposed on the interlayer insulating layer ILD and may cover the first connection electrodes CP1. The first passivation layer PVX1 may have substantially the same thickness along the profiles of the first connection electrodes CP1.

The first insulating layer ISL1 may be disposed on the first passivation layer PVX1. The first insulating layer ISL1 may planarize the upper surface. In the embodiment, the first insulating layer ISL1 may include an organic material.

In the embodiment, the first insulating layer ISL1 may include the trenches TRC that overlap the non-light emitting area NEA. The trenches TRC may include the first and second trenches TRC1 and TRC2. The first trenches TRC1 may be defined between adjacent light emitting areas EMA. The second trenches TRC2 may be defined in areas spaced apart from the light emitting areas EMA and the first trenches TRC1 in a plan view. Gas formed in the first insulating layer ISL1 during the process may be discharged through the first trenches TRC1 and the second trenches TRC2.

The second connection electrodes CP2 may be disposed on the first insulating layer ISL1. The second connection electrodes CP2 may be connected to the first connection electrodes CP1 thereunder.

The second passivation layer PVX2 may be disposed on the first insulating layer ISL1, covering the second connection electrodes CP2. Unlike the first insulating layer ISL1, the second passivation layer PVX2 may include an inorganic material. The second passivation layer PVX2 may have substantially the same thickness along the profiles of the second connection electrodes CP2.

In the embodiment, the second passivation layer PVX2 may define second openings OP2 overlapping the trenches TRC of the first insulating layer ISL1, respectively. The second openings OP2 and the trenches TRC that overlap each other may each have undercut shapes. For example, an area of each of the second openings OP2 may be smaller than an area of each of the trenches TRC. Accordingly, the second passivation layer PVX2 adjacent to the second openings OP2 may protrude from the first insulating layer ISL1 adjacent to the trenches TRC.

The second insulating layer ISL2 may be disposed on the second passivation layer PVX2. The second insulating layer ISL2 may include an organic material. The second insulating layer ISL2 may planarize the upper surface.

In the embodiment, the second insulating layer ISL2 may include first openings OP1 overlapping some of the trenches TRC, respectively. The second insulating layer ISL2 may fill the remaining portions of the trenches TRC except for the portion. In this case, some of the trenches TRC may be the first trenches TRC1. For example, the second insulating layer ISL2 may define the first openings OP1 overlapping the first trenches TRC1, respectively, and may fill the second trenches TRC2.

Accordingly, the first trenches TRC1, the second openings OP2, and the first openings OP1 that overlap each other may form one large trench, respectively, and the second trenches TRC2 and the second openings OP2 that overlap each other may be filled by the second insulating layer ISL2 to be planarized.

The light emitting element layer LDL may be disposed on the second insulating layer ISL2. The light emitting element layer LDL may include the second anode electrode AND2, the third anode electrode AND3, the pixel defining film PDL, the light emitting layer EML, and the cathode electrode CTD.

The anode electrodes AND may be disposed on the second insulating layer ISL2. The second anode electrode AND2 and the third anode electrode AND3 may overlap the second light emitting area EMA2 and the third light emitting area EMA3, respectively. The second anode electrode AND2 and the third anode electrode AND3 may be connected to the second connection electrodes CP2, respectively.

The pixel defining film PDL may be disposed on the anode electrodes AND. The pixel defining film PDL may define an opening exposing a portion of each of the anode electrodes AND. The pixel defining film PDL may cover only the edge of each of the anode electrodes AND, and might not be entirely disposed. For example, the pixel defining film PDL might not overlap the first trenches TRC1, the second openings OP2, and the first openings OP1.

The light emitting layer EML may be disposed on the second insulating layer ISL2, the anode electrodes AND, and the pixel defining film PDL. The light emitting layer EML may entirely extend on the anode electrodes AND and the pixel defining film PDL, and may be disconnected in areas overlapping the first trenches TRC1. For example, the light emitting layer EML may be disconnected in the non-light emitting area NEA between adjacent light emitting areas EMA. Accordingly, the charge generation layers CGL, CGL1′, and CGL2′ of FIG. 6 and FIG. 7 included in the light emitting layer EML may be disconnected between the light emitting areas EMA.

The cathode electrode CTD may be disposed on the light emitting layer EML. Like the light emitting layer EML, the cathode electrode CTD may entirely extend on the light emitting layer EML and may be disconnected in areas overlapping the first trenches TRC1. For example, the cathode electrode CTD may be partially disconnected in the non-light emitting area NEA between adjacent light emitting areas EMA. The cathode electrode CTD is entirely connected on the emission layer EML, so that the light emitting layer EML may be disconnected without affecting the voltage transmission of the cathode electrode CTD.

In the embodiment, the light emitting layer EML is disconnected due to the trenches TRC defined in lower insulating layers (for example, the first and second insulating layers ISL1 and ISL2) and the passivation layer (for example, the second passivation layer PVX2), so that the charge generation layers CGL, CGL1′, and CGL2′ included in the light emitting layer EML may be disconnected between the light emitting areas EMA. Accordingly, color mixing between the sub-pixels may be prevented and leakage current may be prevented when the sub-pixels included in the pixel emit light. In addition, the structure of the display panel may be simplified by disconnecting the light emitting layer EML without adding a separate layer.

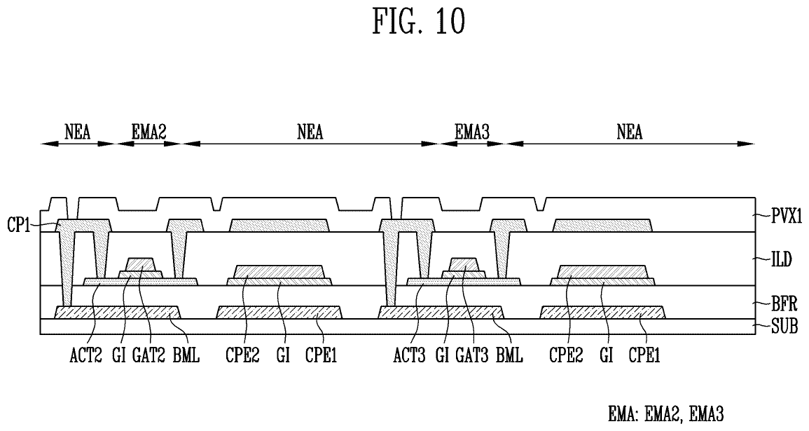

FIG. 10 to FIG. 21 are cross-sectional views illustrating a manufacturing method of the display device according to the embodiment of the present disclosure.

FIG. 10 to FIG. 21 illustrate a method of manufacturing the display device 100 according to the embodiment described above with reference to FIG. 1 to FIG. 9. Accordingly, to the extent that an element is not described in detail with respect to this figure, it may be understood that the element is at least similar to a corresponding element that has been described elsewhere within the present disclosure.

Referring to FIG. 10, the back metal layers BML and the first capacitor electrodes CPE1 may be formed on the substrate SUB including the light emitting areas EMA and the non-light emitting area NEA around the light emitting areas EMA. The buffer layer BFR may be formed on the substrate SUB, covering the back metal layers BML and the first capacitor electrodes CPE1.

The second active electrode ACT2 and the third active electrode ACT3 may be formed on the buffer layer BFR. The gate insulating layer GI may be formed on each of the second active electrode ACT2 and the third active electrode ACT3. In this case, the gate insulating layer GI may be formed to have an island shape. However, embodiments according to the present disclosure are not necessarily limited thereto. The second gate electrode GAT2 may be formed on the gate insulating layer GI on the second active electrode ACT2. The second active electrode ACT2 and the second gate electrode GAT2 may form a second transistor. The third gate electrode GAT3 may be formed on the gate insulating layer GI on the third active electrode ACT3. The third active electrode ACT3 and the third gate electrode GAT3 may form a third transistor.

The gate insulating layers GI may be further formed on the buffer layer BFR. The second capacitor electrodes CPE2 may be formed on the gate insulating layers GI, respectively. The second capacitor electrodes CPE2 overlap the first capacitor electrodes CPE1, respectively, and may form a capacitor.

The interlayer insulating layer ILD may be formed on the buffer layer BFR, covering the second active electrode ACT2, the third active electrode ACT3, the second capacitor electrodes CPE2, the gate insulating layers GI, the second gate electrode GAT2, and the third gate electrode GAT3.

The first connection electrodes CP1 may be formed on the interlayer insulating layer ILD. The first connection electrodes CP1 may be connected to the second active electrode ACT2, the third active electrode ACT3, and the back metal layers BML, which are disposed thereunder, through contact holes formed in the interlayer insulating layer ILD. The first passivation layer PVX1 may be formed on the interlayer insulating layer and may cover the first connection electrodes CP1. In addition, contact holes for contact may be formed in the first passivation layer PVX1.

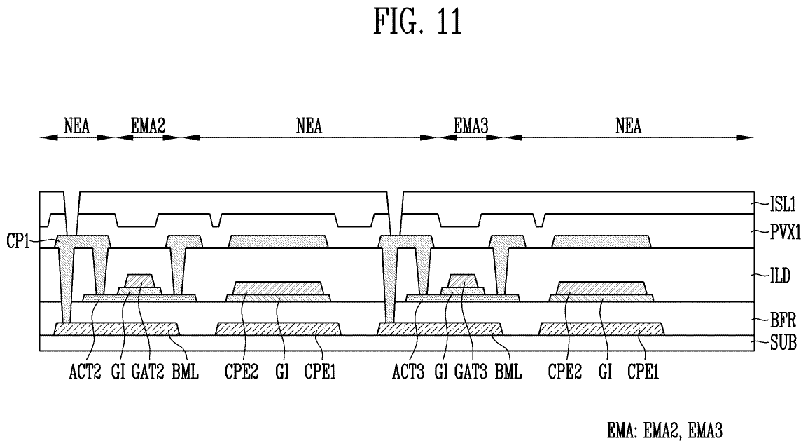

Referring to FIG. 11, the first insulating layer ISL1 may be entirely formed on the first passivation layer PVX1. In the embodiment, the first insulating layer ISL1 may be made of an organic material. In addition, contact holes that overlap the contact holes of the first passivation layer PVX1 may be formed in the first insulating layer ISL1.

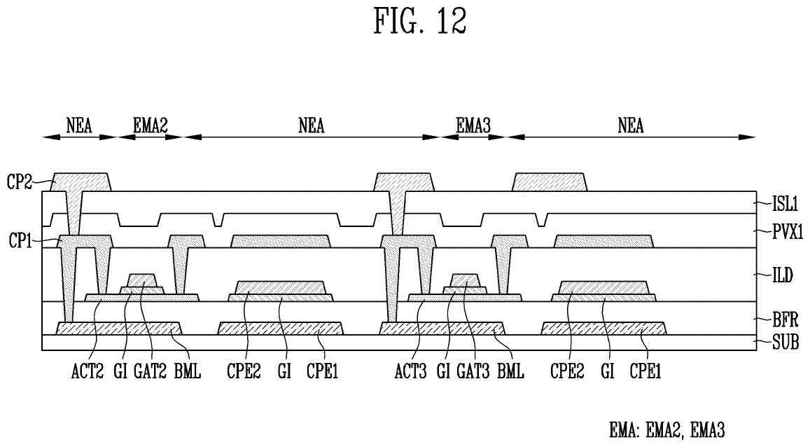

Referring to FIG. 12, the second connection electrodes CP2 may be formed on the first insulating layer ISL1. The second connection electrodes CP2 may be connected to the first connection electrodes CP1 thereunder through contact holes formed in the first passivation layer PVX1 and the first insulating layer ISL1.

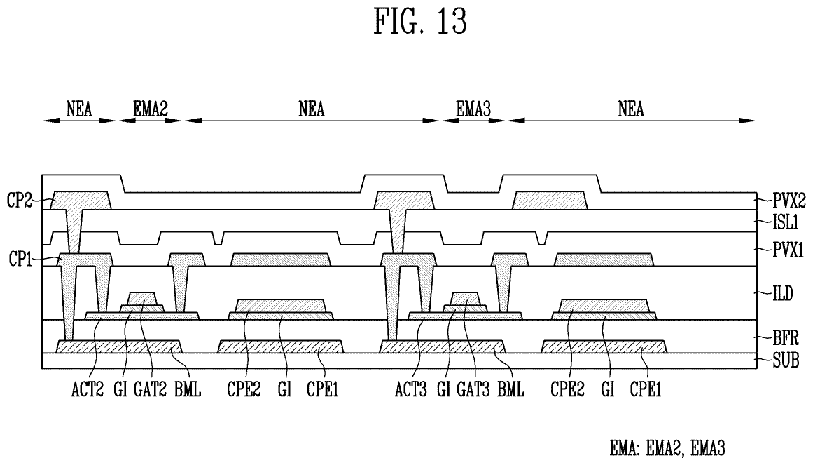

Referring to FIG. 13, the second passivation layer PVX2 may be formed on the first insulating layer ISL1, covering the second connection electrodes CP2. The second passivation layer PVX2 may be made of an inorganic material that is a material different from that of the first insulating layer ISL1.

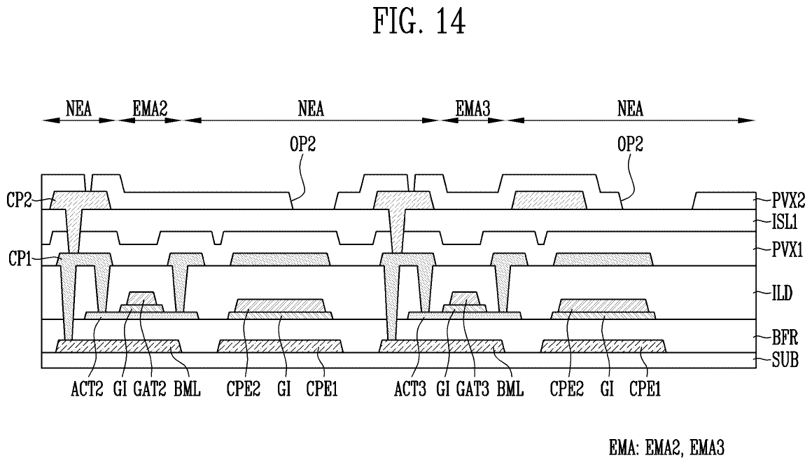

Referring to FIG. 14, contact holes respectively overlapping the second openings OP2 and the second connection electrodes CP2 overlapping the non-light emitting area NEA may be formed in the second passivation layer PVX2. Some of the second openings OP2 may be formed between adjacent light emitting areas EMA, and others thereof may be formed in the non-light emitting area NEA except between the adjacent light emitting areas EMA.

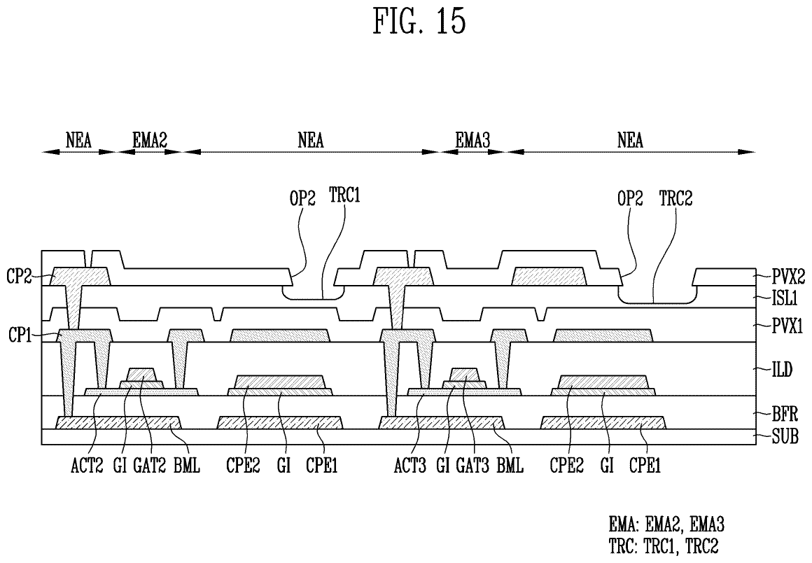

Referring to FIG. 15, the trenches TRC overlapping the non-light emitting area NEA may be formed in the first insulating layer ISL1.

In the embodiment, portions of the first insulating layer ISL1 overlapping the second openings OP2 may be removed through a dry ashing process to form the trenches TRC. In this case, the etch selectivity between organic and inorganic materials may be used. For example, the etching degree of the first insulating layer ISL1 including the organic material may be greater than that of the second passivation layer PVX2 including the inorganic material.

Accordingly, each of the trenches TRC of the first insulating layer ISL1 may be formed to have a larger area than each of the second openings OP2 of the second passivation layer PVX2, in a plan view. For example, each of the second openings OP2 of the second passivation layer PVX2 and each of the trenches TRC of the first insulating layer ISL1 may be formed to have an undercut shape.

The trenches TRC may be configured of the first trenches TRC1 and the second trenches TRC2. The first trenches TRC1 may be trenches TRC formed between adjacent light emitting areas EMA. The first trenches TRC1 may be formed to extend in a length direction of the light emitting areas EMA between adjacent light emitting areas EMA. The second trenches TRC2 may be trenches TRC formed to be spaced apart from the light emitting areas EMA and the first trenches TRC1, in a plan view. For example, among the trenches TRC, except for the first trenches TRC1 formed between the light emitting areas EMA, they may be the second trenches TRC2 (see FIG. 8).

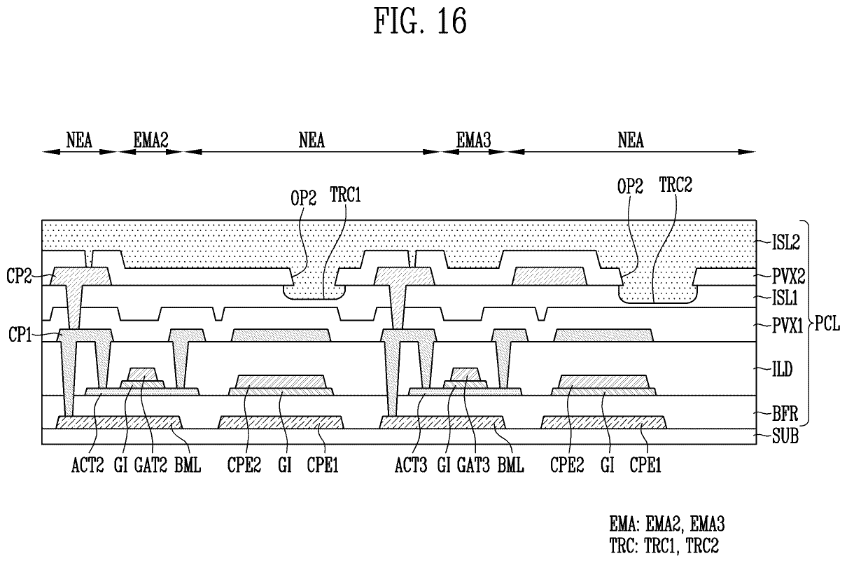

Referring to FIG. 16, the second insulating layer ISL2 may be formed on the second passivation layer PVX2. The second insulating layer ISL2 may be formed by entirely filling the trenches TRC of the first insulating layer ISL1, the second openings OP2 of the second passivation layer PVX2, and the contact holes.

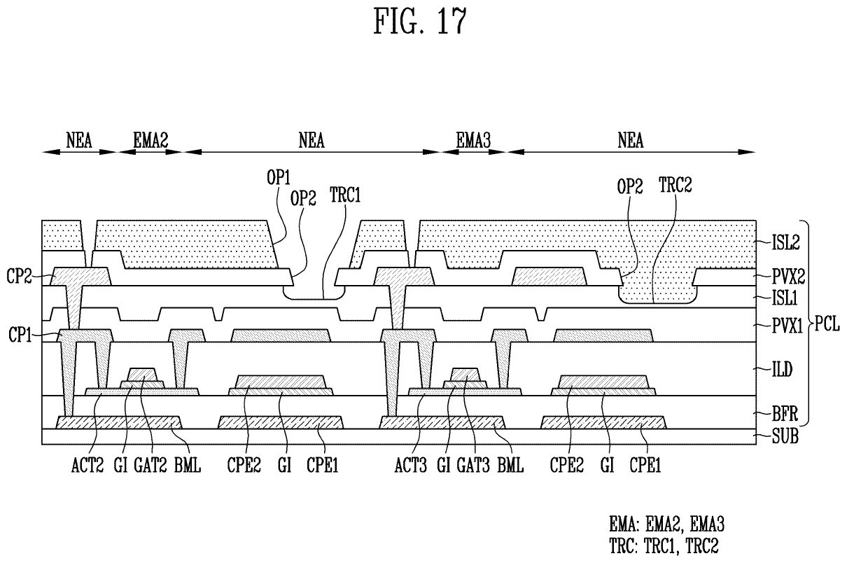

Referring to FIG. 17, contact holes overlapping the first openings OP1 and the second connection electrodes CP2, respectively, may be formed by removing a portion of the second insulating layer ISL2.

For example, the first openings OP1 may be formed in the second insulating layer ISL2 by removing portions of the second insulating layer ISL2, which overlaps some of the trenches TRC, respectively. In this case, some of the trenches TRC may mean the first trenches TRC1. For example, the first openings OP1 may be formed in areas that overlap the first trenches TRC1 and the second openings OP2, respectively.

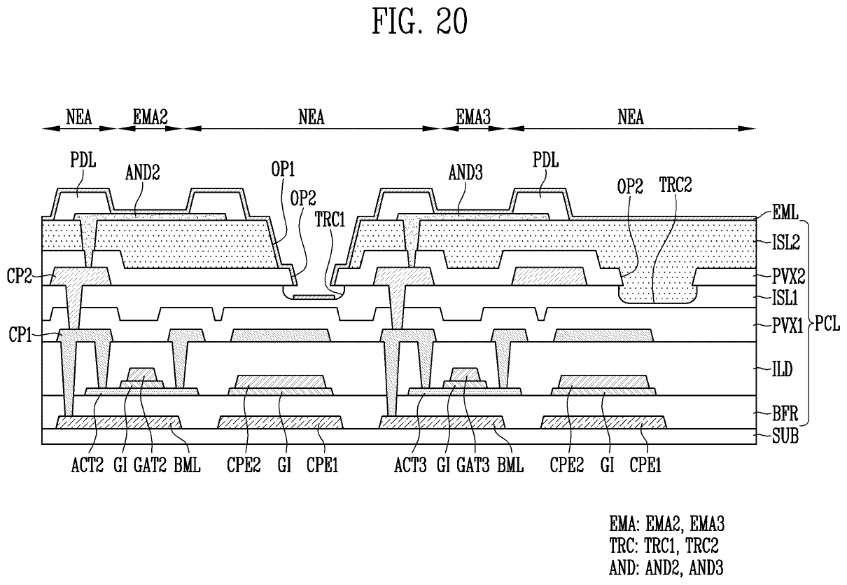

In this case, since the second trenches TRC2 are used to discharge gas generated in the first insulating layer ISL1 and are not disposed between the light emitting areas EMA and thus cannot disconnect the light emitting layer EML (see FIG. 20), they may be filled by the second insulating layer ISL2 to be planarized.

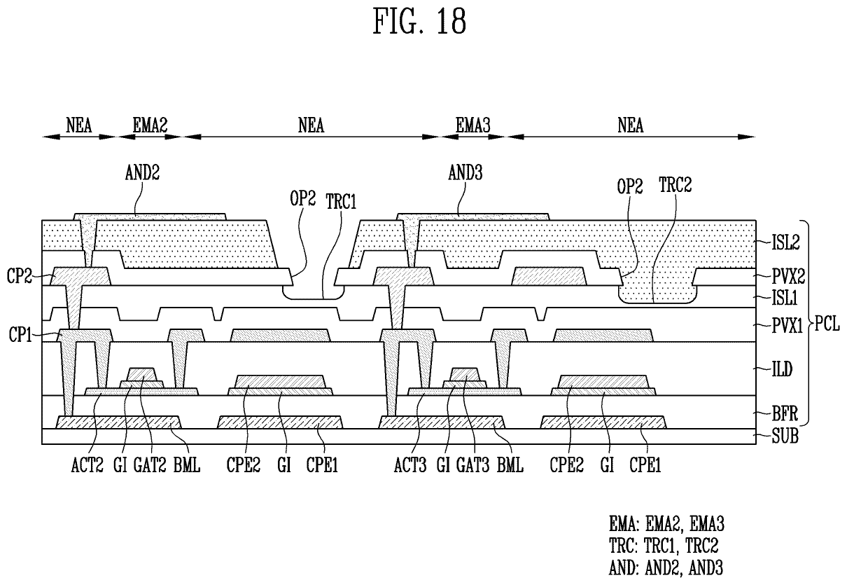

Referring to FIG. 18, the anode electrodes AND may be formed on the second insulating layer ISL2. The anode electrodes AND may be formed to overlap the light emitting areas EMA, respectively. For example, the second anode electrode AND2 may overlap the second light emitting area EMA2, and the third anode electrode AND3 may overlap the third light emitting area EMA3. The anode electrodes AND may be connected to the second connection electrodes CP2 thereunder through the contact holes formed in the second passivation layer PVX2 and the second insulating layer ISL2.

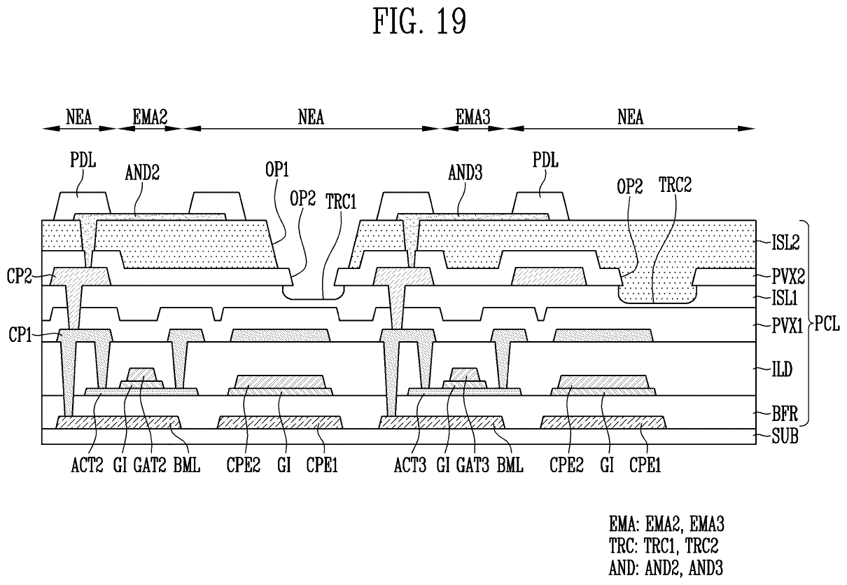

Referring to FIG. 19, the pixel defining film PDL may be formed on the second insulating layer ISL2 and the anode electrodes AND. An opening exposing a portion of each of the anode electrodes AND may be formed in the pixel defining film PDL. The pixel defining film PDL may cover only the edge of each of the anode electrodes AND, and may be formed in an area that does not overlap the first trenches TRC1, the second openings OP2, and the first openings OP1.

Referring to FIG. 20, the light emitting layer EML may be formed on the second insulating layer ISL2, the anode electrodes AND, and the pixel defining film PDL. The light emitting layer EML may be entirely deposited on the light emitting areas EMA and the non-light emitting area NEA using an open mask.

Even when the light emitting layer EML is entirely deposited, since each of the second openings OP2 and each of the first trenches TRC1 have an undercut shape, it may be difficult for the light emitting layer EML to be entirely extended and deposited inside each of the first trenches TRC1. Accordingly, the light emitting layer EML may be disconnected in areas overlapping the first trenches TRC1 of the first insulating layer ISL1, respectively. For example, since the second passivation layer PVX2 adjacent to the second openings OP2 protrudes from the first insulating layer ISL1 adjacent to the first trenches TRC1, the light emitting layer EML extends and is deposited only up to the side surfaces of the second openings OP2, and might not extend but may be disconnected in the first trenches TRC1.

Accordingly, the light emitting layer EML may be partially disconnected between adjacent light emitting areas EMA. For example, the light emitting layer EML may be partially disconnected between adjacent anode electrodes AND.

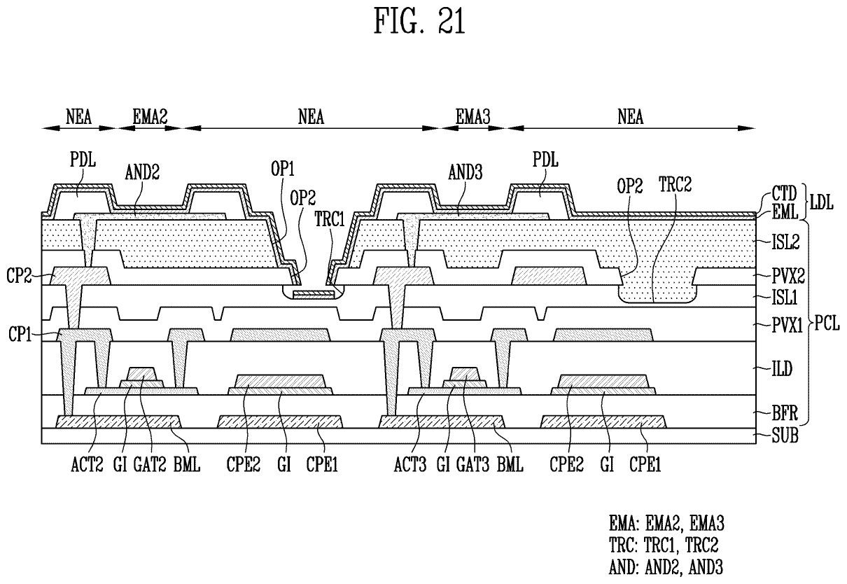

Referring to FIG. 21, the cathode electrode CTD may be formed on the light emitting layer EML. The cathode electrode CTD may also be entirely deposited on the light emitting areas EMA and the non-light emitting area NEA using an open mask.

Even when the cathode electrode CTD is entirely deposited, since each of the second openings OP2 and each of the first trenches TRC1 have an undercut shape, the cathode electrode CTD may be disconnected in areas overlapping the first trenches TRC1 of the first insulating layer ISL1, respectively.

Accordingly, the cathode electrode CTD may be partially disconnected between adjacent light emitting areas EMA. For example, the cathode electrode CTD may be partially disconnected between adjacent anode electrodes AND. However, the cathode electrode CTD may entirely extend except for areas overlapping the first trenches TRC1.

In the embodiment, even when the light emitting layer EML is entirely deposited in the light emitting areas EMA and the non-light emitting area NEA, the light emitting layer EML is partially disconnected between the light emitting areas EMA due to the undercut shapes of the first trenches TRC1, the second openings OP2, and the first openings OP1, thereby preventing color mixing between the light emitting areas EMA and preventing leakage current. In addition, by forming the first trenches TRC1, the second openings OP2, and the first openings OP1 in the existing layers (for example, the first insulating layer ISL1, the second passivation layer PVX2, and the second insulating layer ISL2), respectively, a process and a mask for forming a separate layer are not added, so that process costs may be reduced and process efficiency may be increased.

A display device according to an embodiment is applicable to various types of electronic devices. In an embodiment, an electronic device includes the above-described display device and may further include other modules or devices having additional functions in addition to the display device.

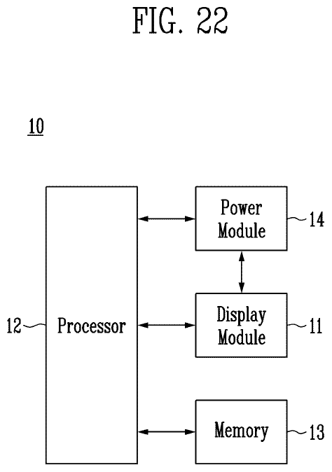

FIG. 22 is a block diagram of an electronic device according to an embodiment.

Referring to FIG. 1, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

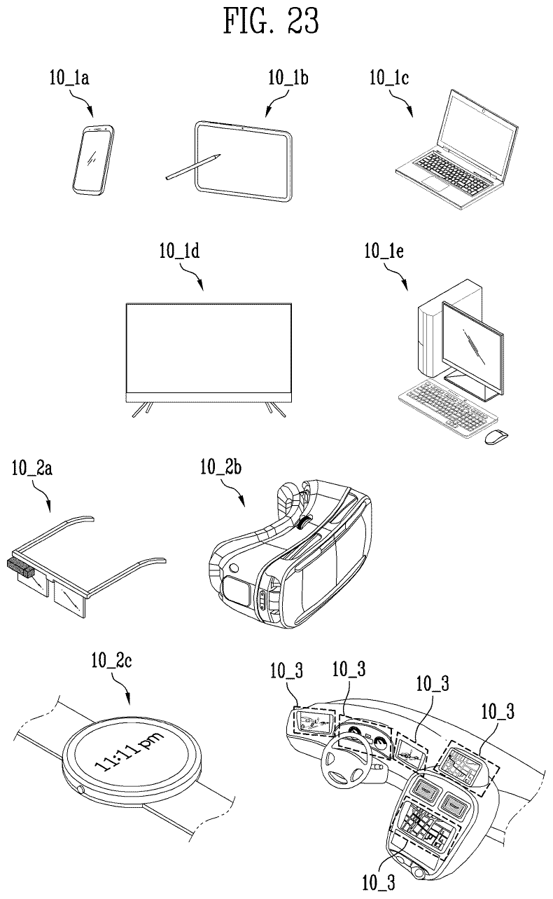

FIG. 23 shows schematic views of various embodiments of an electronic device.

Referring to FIG. 2, various types of electronic devices to which embodiments of a display device are applied may include an electronic device to display images such as a smartphone 10_1a, a tablet PC 10_1b, a laptop computer 10_1c, a television (TV) 101d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

The technical idea of the present disclosure has been specifically described according to various embodiments, but it should be noted that the foregoing embodiments are provided only for illustration while not necessarily limiting the present disclosure. It will be understood by those skilled in the art that various changes in form and details may be made therein without departing from the scope of the present disclosure.

All changes or modifications of the embodiments described herein and their equivalents will be interpreted as included the range of the present disclosure.

What is claimed is:

1. A display device, comprising:
a substrate including light emitting areas and a non-light emitting area proximate to the light emitting areas;
anode electrodes disposed on the substrate and respectively overlapping the light emitting areas;
a first insulating layer disposed between the substrate and the anode electrodes and including trenches overlapping the non-light emitting area; and
a second insulating layer disposed between the first insulating layer and the anode electrodes, the second insulating layer including first openings respectively overlapping some of the trenches, and filling others of the trenches.

2. The display device of claim 1, wherein the trenches include:
first trenches that are defined between adjacent pairs of the anode electrodes; and
second trenches that are spaced apart from the anode electrodes and the first trenches in a plan view.

3. The display device of claim 2,
wherein the second insulating layer fills the second trenches, and
wherein the first openings overlap the first trenches, respectively.

4. The display device of claim 2, further comprising a passivation layer disposed between the first insulating layer and the second insulating layer and including a material that is different from that of the first insulating layer.

5. The display device of claim 4, wherein the passivation layer defines second openings that respectively overlap the trenches.

6. The display device of claim 5, wherein each of the second openings and each of the trenches have an undercut shape.

7. The display device of claim 6, further comprising a light emitting layer disposed on the anode electrodes.

8. The display device of claim 7, wherein the light emitting layer is disconnected in areas overlapping the first trenches.

9. The display device of claim 8, further comprising a cathode electrode disposed on the light emitting layer.

10. The display device of claim 9, wherein the cathode electrode is disconnected in areas overlapping the first trenches.

11. A method of manufacturing a display device, comprising:
forming a first insulating layer on a substrate that includes light emitting areas and a non-light emitting area proximate to the light emitting areas;
forming trenches in the first insulating layer overlapping the non-light emitting area;
forming a second insulating layer filling the trenches on the first insulating layer;
forming first openings in the second insulating layer by removing portions of the second insulating layer that overlap some of the trenches, respectively; and
forming anode electrodes respectively overlapping the light emitting areas on the second insulating layer.

12. The method of claim 11,
wherein the trenches include first trenches and second trenches, and
wherein the forming of the trenches includes:
forming the first trenches between proximate pairs of the light emitting areas; and
forming the second trenches spaced apart from the light emitting areas and the first trenches in a plan view.

13. The method of claim 12, wherein the forming of the first openings includes removing portions of the second insulating layer respectively overlapping the first trenches.

14. The method of claim 13, further comprising:
after the forming of the first insulating layer and before the forming of the trenches in the first insulating layer, forming a passivation layer on the first insulating layer using a material that is different from that of the first insulating layer.

15. The method of claim 14, further comprising:
before the forming of the trenches, forming second openings overlapping the non-light emitting area in the passivation layer.

16. The method of claim 15, wherein the trenches are formed by removing portions of the first insulating layer overlapping the second openings through an ashing process.

17. The method of claim 16, wherein each of the second openings and each of the trenches are formed to have an undercut shape.

18. The method of claim 17, further comprising forming a light emitting layer on the anode electrodes so as to be disconnected in areas overlapping the first trenches.

19. The method of claim 18, further comprising forming a cathode electrode on the light emitting layer so as to be disconnected in areas overlapping the first trenches.

20. The method of claim 14,
wherein the first insulating layer is made of an organic material, and
wherein the passivation layer is made of an inorganic material.

21. An electronic device, comprising:
a processor to provide input image data; and
a display device to display an image based on the input image data,
wherein the display device comprises: a substrate including light emitting areas and a non-light emitting area proximate to the light emitting areas;
anode electrodes disposed on the substrate and respectively overlapping the light emitting areas;
a first insulating layer disposed between the substrate and the anode electrodes and including trenches overlapping the non-light emitting area; and
a second insulating layer disposed between the first insulating layer and the anode electrodes, the second insulating layer including first openings respectively overlapping some of the trenches, and filling others of the trenches.
